(19) United States
(12) Patent Application Publication
(10) Pub. No.: US 2025/0194366 A1
(43) Pub. Date: Jun. 12, 2025

(54) DISPLAY PANEL AND DISPLAY DEVICE

(71) Applicant: BOE Technology Group Co., Ltd., Beijing (CN)

(72) Inventors: Hao LIU, Beijing (CN); Hao ZHANG, Beijing (CN); Chunyan XIE, Beijing (CN); Libin LIU, Beijing (CN)

(73) Assignee: BOE Technology Group Co., Ltd., Beijing (CN)

(21) Appl. No.: 18/856,073

(22) PCT Filed: Jan. 17, 2024
(86) PCT No.: PCT/CN2024/072741

§ 371 Date: Oct. 11, 2024

(30) Foreign Application Priority Data
Feb. 1, 2023 (CN) 202310126947.6

(51) Int. Cl. H10K 59/131; G09G 3/00; G09G 3/3266

(52) U.S. Cl. CPC H10K 59/1315; G09G 3/006; G09G 3/3266; G09G 2330/12

(57) ABSTRACT

A display panel includes a first display portion, a second display portion, and a first bonding portion connected to the first display portion. The first display portion surrounds the second display portion in an enclosed state, and forms an included angle with the second display portion. The first bonding portion can be bent to a non-display surface of the second display portion. The first display portion includes a first display area and a first peripheral area. The first display area is provided with a plurality of first sub-pixels. The first peripheral area is located on a side of the first display area away from the second display portion and is provided with a first voltage bus, first circuit structures, first data fan-out lines and a second voltage bus that are connected to the plurality of first sub-pixels and extend to the first bonding portion.

### CROSS-REFERENCE TO RELATED APPLICATIONS

This application is a national phase entry under 35 USC 371 of International Patent Application No. PCT/CN2024/072741, filed on Jan. 17, 2024, which claims priority to Chinese Patent Application No. 202310126947.6, filed on Feb. 1, 2023, each are incorporated herein by reference in their entirety.

### TECHNICAL FIELD

The present disclosure relates to the field of display technologies, and in particular, to a display panel and a display device.

### BACKGROUND

Organic light-emitting diode (OLED) display panels have gradually become one of the mainstream products in the display field due to self-luminescence, no need for backlight, high contrast, thin thickness, wide viewing angle, fast response speed, capable of being used for flexible panels, wide operating temperature range, simple structure and process, and other excellent performance. OLED display panels may be widely used in terminal products such as smart phones, tablets, TVs and wearable devices (such as watches).

A conventional wearable device, such as a watch, includes a display area (display screen). In order to save power, the watch is usually in a screen-off state (a mode in which no image information is displayed) in a non-wrist-raising state. When display is needed, the entire display screen emits light for display, and the usage mode is single.

### SUMMARY

In an aspect, a display panel is provided. The display panel includes a first display portion, a second display portion and a first bonding portion. The first display portion surrounds the second display portion in an enclosed state and has an included angle with the second display portion. The second display portion includes a display surface and a non-display surface that are opposite to each other. The first bonding portion is disposed on a side of the first display portion and connected to the first display portion. The first bonding portion is capable of being bent to the non-display surface of the second display portion. The first display portion includes a first display area and a first peripheral area. The first display area is provided with a plurality of first sub-pixels therein. The first peripheral area extends in parallel with the first display area and is located on a side of the first display area away from the second display portion. The first peripheral area is provided therein with a first voltage bus, first circuit structures, first data fan-out lines and a second voltage bus that are connected to the plurality of first sub-pixels. The first voltage bus, the first circuit structures, the first data fan-out lines and the second voltage bus extend to the first bonding portion, and the first bonding portion is configured to transmit corresponding signals to the first voltage bus, the first circuit structures, the first data fan-out lines and the second voltage bus.

In some embodiments, the second display portion includes a second display area and a second peripheral area. The second display area is provided with a plurality of second sub-pixels therein. The second peripheral area surrounds the second display area. The second peripheral area is at least provided therein with second circuit structures and second data fan-out lines that are connected to the plurality of second sub-pixels. The display panel further includes a second bonding portion. The second bonding portion is disposed on a side of the second display portion and connected to the second display portion. The second bonding portion is capable of being bent to the non-display surface of the second display portion. The second circuit structures and the second data fan-out lines extend to the second bonding portion, and the second bonding portion is configured to transmit corresponding signals to the second circuit structures and the second data fan-out lines.

In some embodiments, the second peripheral area is further provided therein with a third voltage bus and a fourth voltage bus that are connected to the plurality of second sub-pixels. The third voltage bus and the fourth voltage bus extend to the second bonding portion, and the second bonding portion is further configured to transmit corresponding signals to the third voltage bus and the fourth voltage bus.

In some embodiments, the first display portion includes a connecting sub-portion and two extending sub-portions. The connecting sub-portion is located between the first bonding portion and the second display portion and connected to the second display portion. The two extending sub-portions are respectively connected to two ends of the connecting sub-portion. Each of the two extending sub-portions of the first display portion and the second display portion have a gap therebetween in a flattened state. The second peripheral area includes a second fan-out area and second wiring areas located at two sides of the second fan-out area. In a second wiring area, in a direction from the second display area to the second wiring area, the third voltage bus, the second circuit structures, the second data fan-out lines and the fourth voltage bus are arranged in sequence. In the second fan-out area, in an extension direction of an edge of the second fan-out area proximate to the second bonding portion, the fourth voltage bus, a second data fan-out line, the third voltage bus, the second circuit structures, the third voltage bus, a second data fan-out line and the fourth voltage bus are arranged in sequence.

In some embodiments, a line width of the first voltage bus is substantially equal to a line width of the third voltage bus; and/or a line width of the second voltage bus is greater than a line width of the fourth voltage bus.

In some embodiments, a line width of a portion of the first voltage bus located in the second peripheral area is in a range of 30 μm to 130 μm, inclusive; a line width of a portion of the second voltage bus located in the second peripheral area is in a range of 400 μm to 500 μm, inclusive; a line width of a portion of the third voltage bus located in the second peripheral area is in a range of 30 μm to 130 μm, inclusive; and a line width of a portion of the fourth voltage bus located in the second peripheral area is in a range of 130 μm to 230 μm, inclusive.

In some embodiments, the first voltage bus and the second voltage bus are connected to the plurality of second sub-pixels.

In some embodiments, the first display portion includes a connecting sub-portion and two extending sub-portions. The connecting sub-portion is located between the first bonding portion and the second display portion and connected to the second display portion. The two extending sub-portions are respectively located at two sides of the connecting sub-portion and connected to two ends of the connecting sub-portion. The display panel further includes two connecting portions. Each connecting portion in the two connecting portions is located between an extending sub-portion and the second display portion and is connected to both the extending sub-portion and the second display portion. The connecting portion is capable of being stretched to be deformed. The connecting portion includes a first voltage transfer line and a second voltage transfer line, the first voltage transfer line is connected to the first voltage bus and the plurality of second sub-pixels, and the second voltage transfer line is connected to the second voltage bus and the plurality of second sub-pixels.

In some embodiments, the connecting portion is provided with a plurality of openings therein, and the first voltage transfer line and the second voltage transfer line are disposed bypassing the plurality of openings.

In some embodiments, the second peripheral area includes a second fan-out area and second wiring areas located at two sides of the second fan-out area. In a second wiring area, the second circuit structures are closer to the second display area than the second data fan-out lines. In the second fan-out area, in an extension direction of an edge of the second fan-out area proximate to the second bonding portion, a second data fan-out line, the second circuit structures, and a second data fan-out line are arranged in sequence.

In some embodiments, the first bonding portion and the second bonding portion are disposed on two opposite sides of the second display portion. Each of ends of the two extending sub-portions away from the connecting sub-portion and the second bonding portion have a gap therebetween.

In some embodiments, the second display portion includes a plurality of second sub-pixels. The first voltage bus, the first circuit structures and the second voltage bus are further connected to the plurality of second sub-pixels.

In some embodiments, the first display portion includes a connecting sub-portion and two extending sub-portions. The connecting sub-portion is located between the first bonding portion and the second display portion and connected to the second display portion. The two extending sub-portions are respectively located at two sides of the connecting sub-portion and connected to two ends of the connecting sub-portion.

The display panel further includes two connecting portions. Each connecting portion in the two connecting portions is located between an extending sub-portion and the second display portion and is connected to both the extending sub-portion and the second display portion. The connecting portion is capable of being stretched to be deformed. The connecting portion includes a first voltage transfer line, a second voltage transfer line, a gate signal transfer line and a data signal transfer line. The first voltage transfer line is connected to the first voltage bus and the plurality of second sub-pixels, the second voltage transfer line is connected to the second voltage bus and the plurality of second sub-pixels, and the gate signal transfer line and the data signal transfer line are connected to the first circuit structures and the plurality of second sub-pixels. In some embodiments, the connecting portion is provided with a plurality of openings therein, and the first voltage transfer line, the second voltage transfer line, the gate signal transfer line and the data signal transfer line are disposed bypassing the plurality of openings.

In some embodiments, the first peripheral area includes a first fan-out area and two first wiring areas located at two sides of the first fan-out area. In each first wiring area, in a direction perpendicular to an extension direction of the first display area and from the first display area to the first wiring area, the first voltage bus, the first circuit structures, the first data fan-out lines and the second voltage bus are arranged in sequence. In the first fan-out area, in an extension direction of an edge of the first fan-out area proximate to the first bonding portion, the second voltage bus, a first data fan-out line, the first voltage bus, the first circuit structures, the first voltage bus, a first data fan-out line and the second voltage bus are arranged in sequence.

In some embodiments, the first display portion further includes a third peripheral area. The third peripheral area extends in parallel with the first display area and is located between the first display area and the second display portion. The third peripheral area is provided therein with another second voltage bus connected to the plurality of first sub-pixels.

In some embodiments, the first display portion includes a plurality of first sub-pixels, and the plurality of first sub-pixels are arranged in a plurality of rows and a plurality of columns. The second display portion includes a plurality of second sub-pixels, and the plurality of second sub-pixels are arranged in a plurality of rows and a plurality of columns. A projection of a row direction in which the plurality of first sub-pixels are arranged on a reference plane is parallel to a projection of a row direction in which the plurality of second sub-pixels are arranged on the reference plane, and a projection of a column direction in which the plurality of first sub-pixels are arranged on the reference plane is parallel to a projection of a column direction in which the plurality of second sub-pixels are arranged on the reference plane. The reference plane is a plane where the display surface of the second display portion is located.

In some embodiments, the second display portion is circular, and the first display portion is annular in the enclosed state. A radius of the second display portion is R₁, and a width of the first display portion is L; a radius of a circle where an inner border of the first display portion in a flattened state is located is R₂; an included angle between the second display portion and the first display portion in the enclosed state is α; and a thickness of the display panel is H; wherein H=L Sin(π−α) and

$${R}_{2} = \frac{{R}_{1} L}{\sqrt{{L}^{2} - {H}^{2}}} .$$

In some embodiments, a first circuit structure includes a first gate driver circuit, a first test circuit and a first multi-path selection circuit; the first gate driver circuit, the first test circuit and the first multi-path selection circuit are arranged side by side in an extension direction of the first peripheral area. And/or a second circuit structure includes a second gate driver circuit, a second test circuit and a second multi-path selection circuit; the second gate driver circuit, the second test circuit and the second multi-path selection circuit are arranged side by side in an extension direction of the second peripheral area.

In another aspect, a display device is provided. The display device includes a first driver chip and the display panel as described in any of the above embodiments. The first driver chip is disposed on the first bonding portion of the display panel and configured to transmit a signal to the first bonding portion.

In some embodiments, the display panel further includes a second bonding portion, and the second bonding portion is connected to the second display portion of the display panel. The display device further includes a second driver chip. The second driver chip is disposed on the second bonding portion and configured to transmit a signal to the second bonding portion.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display device, in accordance with some embodiments;

FIG. 2 is a plane structural diagram of a display panel, in accordance with some embodiments;

FIG. 3 is a three-dimensional structural diagram of a display panel, in accordance with some embodiments;

FIG. 4 is a side view of a display panel, in accordance with some embodiments;

FIG. 5 is a partial enlarged view of an area A in FIG. 2;

FIG. 6A is a partial enlarged view of an area B in FIG. 2;

FIG. 6B is another partial enlarged view of an area B in FIG. 2;

FIG. 7 is a plane structural diagram of another display panel, in accordance with some embodiments;

FIG. 8 is a partial enlarged view of an area C in FIG. 7;

FIG. 9 is a partial enlarged view of an area D in FIG. 7;

FIG. 10 is a plane structural diagram of yet another display panel, in accordance with some embodiments;

FIG. 11 is a partial enlarged view of an area E in FIG. 10;

FIG. 12 is a partial enlarged view of an area F in FIG. 10;

FIG. 13 is a plane structural diagram of yet another display panel, in accordance with some embodiments;

FIG. 14A is a partial enlarged view of an area G in FIG. 13;

FIG. 14B is another partial enlarged view of an area G in FIG. 13;

FIG. 15 is a top view of a display panel, in accordance with some embodiments; and

FIG. 16 is a structural diagram of a first display portion and a second display portion, in accordance with some embodiments.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. For example, the term “connected” may be used in the description of some embodiments to indicate that two or more components are in direct physical or electrical contact with each other. As another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

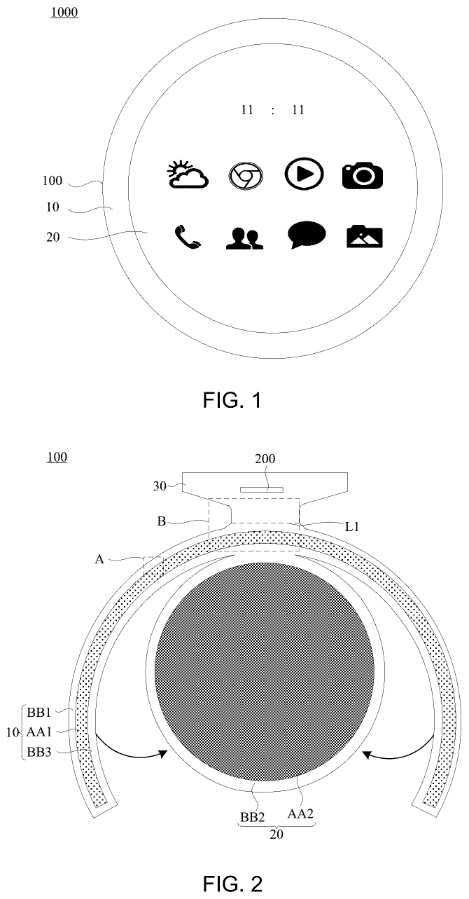

Some embodiments of the present disclosure provide a display device 1000. As shown in FIG. 1, the display device 1000 may be any device that can display images whether in motion (e.g., video) or stationary (e.g., a still image), and regardless of text or image. For example, the display device 1000 may be any product or component having a display function, such as a television, a notebook computer, a tablet computer, a mobile phone, an electronic photo, an electronic billboard or sign, a personal digital assistant (PDA), a navigator, a wearable device, an augmented reality (AR) device, or a virtual reality (VR) device. For example, the display device 1000 is a watch.

For example, the display device 1000 may be an organic light-emitting diode (OLED) display device, a quantum dot light-emitting diode (QLED) display device, or an active matrix organic light-emitting diode (AMOLED) display device, which is not specifically limited in embodiments of the present disclosure.

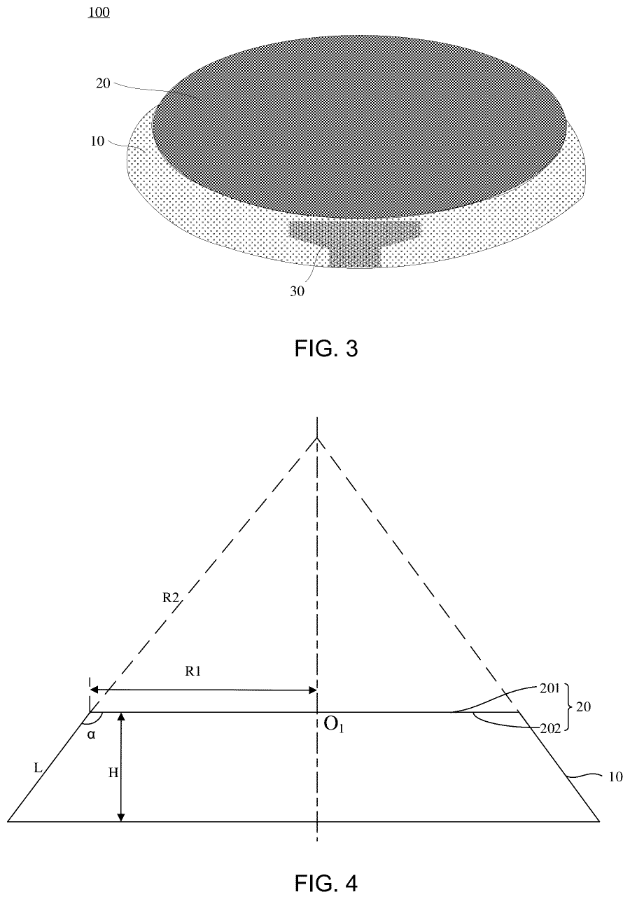

In some embodiments, as shown in FIGS. 2 and 3, FIG. 2 is a structural diagram of a display panel 100 in a flattened state (a first display portion is in a flattened state), and FIG. 3 is a structural diagram of the display panel 100 when the first display portion is in an enclosed state, that is, a structural diagram of the first display portion 10 in an enclosed state. The display device 1000 includes a display panel 100 and a first driver chip 200. The display panel 100 includes a first display portion 10, a second display portion 20 and a first bonding portion 30.

For example, as shown in FIG. 2, the first display portion 10, the second display portion 20 and the first bonding portion 30 are integrally provided. The integral provision means that in a process of manufacturing the display panel 100, pixel circuits, light-emitting devices and an encapsulation structure may be formed in sequence on the same substrate, for example, a flexible substrate made of a resin material. Then, the display panel 100 is divided into a first area, a second area and a third area. The substrate, pixel circuits, light-emitting devices and the encapsulation structure included in the first area constitute a first display portion 10. The substrate, pixel circuit(s), light-emitting device(s) and the encapsulation structure included in the second area constitute a second display portion 20. The substrate, an array substrate and the encapsulation structure included in the third area constitute a first bonding portion 30. In this way, the first display portion 10, the second display portion 20 and the first bonding portion 30 are integrally provided.

It can be understood that the first display portion 10 and the second display portion 20 both include pixel circuits and light-emitting devices, that is, the first display portion 10 and the second display portion 20 both include sub-pixels. Therefore, the first display portion 10 and the second display portion 20 may both display images. For example, in the embodiments of the present disclosure, description is made by taking an example where the first display portion 10 includes first sub-pixels P1 and the second display portion 20 includes second sub-pixels P2.

As shown in FIG. 2, the first display portion 10 is connected to the second display portion 20. As shown in FIG. 3, the first display portion 10 may be bent to enclose the second display portion 20, so that the first display portion 10 can surround the second display portion 20. The first display portion 10 and the second display portion 20 have an included angle. For example, in a case where FIG. 2 shows display surfaces of the first display portion 10 and the second display portion 20, directions of arrows in FIG. 2 are an closing direction of two side areas of the first display portion 10, that is, the two side areas of the first display portion 10 are bent along the directions of the arrows to form a structure shown in FIG. 3.

As shown in FIG. 4, FIG. 4 is a side view of the first display portion 10 and the second display portion 20. The first display portion 10 surrounds the second display portion 20 in an enclosed state, and there is an included angle α between the first display portion 10 and the second display portion 20. For example, the angle α may be a right angle or an obtuse angle, which is beneficial for users to viewing image information displayed by the first display portion 10. For example, the angle α may be in a range of 90° to 150°, inclusive, such as 90°, 120°, 135° or 150°, which is not specifically limited in the embodiments of the present disclosure.

It can be understood that the first display portion 10 and the second display portion 20 each include a display surface and a non-display surface that are opposite to each other. Taking the second display portion 20 as an example, the display surface 201 of the second display portion 20 refers to a surface (an upper surface of the second display portion 20 in FIG. 4) of the second display portion 20 used to display images, and the non-display surface 202 of the second display portion 20 refers to another surface (a lower surface of the second display portion 20 in FIG. 4) of the second display portion 20 opposite to the display surface. The included angle α between the first display portion 10 and the second display portion 20 may be understood as an included angle formed between the non-display surface of the first display portion 10 and the non-display surface of the second display portion 20.

As shown in FIG. 3, the second display portion 20 may, for example, form a main display screen of the display device 1000, and the first display portion 10 may, for example, form a side display screen of the display device 1000. In this way, the display device 1000 may be a display device with a side display function.

The first display portion 10 and the second display portion 20 may perform independent display, and/or the first display portion 10 and the second display portion 20 may perform synchronous display. For example, in a case where the first display portion 10 and the second display portion 20 perform independent display, taking the watch as an example, when the watch is in a non-wrist-raising state, only the first display portion 10 may perform display, for example, display battery level, time or other functional graphic information. In this way, a display area of display device 1000 may be reduced, and energy consumption may be reduced. When the watch is in a wrist-raising state, only the second display portion 20 may perform display to increase a display area of the display device. Alternatively, the first display portion 10 and the second display portion 20 may perform display at different refresh rates. For example, a refresh rate of the first display portion 10 in the non-wrist-raising state is smaller than a refresh rate of the second display portion 20 in the wrist-raising state. Alternatively, in the wrist-raising state, the first display portion 10 and the second display portion 20 may synchronously display images (e.g., refresh rates of the first display portion 10 and the second display portion 20 are the same). Due to a difference between a distance between the first display portion 10 and the human eye and a distance between the second display portion 20 and the human eye, the human eye may observe 3D displayed images, that is, the display device may have a naked-eye 3D display effect. Alternatively, in the wrist-raising state, the first display portion 10 and the second display portion 20 may display different image information. In the embodiments of the present disclosure, specific display methods of the first display portion 10 and the second display portion 20 are not specifically limited. Based on the above contents, the display panel 100 provided in the embodiments of the present disclosure may enrich usage scenarios of the display device 1000 and thus improve the user experience.

As shown in FIG. 2, the first bonding portion 30 is disposed on a side of the first display portion 10 and is connected to the first display portion 10. As shown in FIG. 3, the first bonding portion 30 may be bent to the non-display surface of the second display portion 20, so as to reduce an influence of the first bonding portion 30 on a width of a frame of the display device 1000, which is beneficial for the display device 1000 to achieving a narrow frame.

As shown in FIG. 2, the first display portion 10 includes a first display area AA1 and a first peripheral area BB1. The first peripheral area BB1 extends in parallel with the first display area AA1 and is located on a side of the first display area AA1 away from the second display portion 20. That is, the first peripheral area BB1 and the first display area AA1 have the same extension direction and approximately the same extension length. For example, the first peripheral area BB1 and the first display area AA1 are both in arc shapes, and a length of the first peripheral area BB1 is slightly larger than a length of the first display area AA1, so that the first display portion 10 can surround and protect the first display area AA1 in an enclosed state.

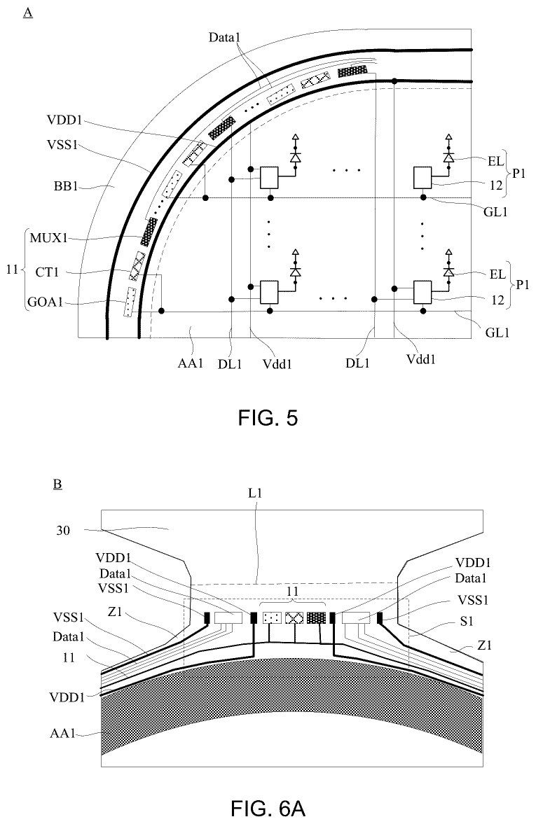

For example, referring to FIG. 5, FIG. 5 is a partial enlarged view of the first display portion 10, and the first display area AA1 is provided with a plurality of first sub-pixels P1. The first display area AA1 further includes a plurality of first voltage signal lines Vdd1, a plurality of first gate lines GL1 and a plurality of first data lines DL1. The first sub-pixel P1 includes a pixel circuit 12 and a light-emitting device EL.

For example, the pixel circuit 12 may include a plurality of switching devices and at least one capacitor Cst. The switching device may, for example, include a thin film transistor (TFT), a field effect transistor, or other switching devices with the same characteristics, which is not specifically limited in the embodiments of the present disclosure. For example, the embodiments of the present disclosure will be exemplarily described by taking an example where the switching device is the TFT.

For example, the pixel circuit 12 may include a plurality of TFTs and at least one capacitor Cst. For example, the pixel circuit is a “3T1C circuit”, a “7T1C circuit”, an “8T1C circuit” or any other pixel circuit, which is not specifically limited in the embodiments of the present disclosure. It can be understood that “T” represents a TFT, the number before “T” represents the number of the TFTs, “C” represents a capacitor, and the number before “C” represents the number of the capacitor(s) Cst.

Referring to FIG. 5, the first peripheral area BB1 is provided with a first voltage bus VDD1, first circuit structures 11, first data fan-out lines Data1, and a second voltage bus VSS1 that are connected to the plurality of first sub-pixels P1.

For example, referring to FIG. 5, the first voltage bus VDD1 is connected to the plurality of first sub-pixels P1 by the first voltage signal lines Vdd1, and the first voltage bus VDD1 is used to provide a positive power supply voltage signal (high voltage signal) for the first sub-pixels P1.

The first circuit structure 11 may include, for example, a first gate driver circuit GOA1, a first test unit CT1 and a first multi-path selection circuit MUX1. The first gate driver circuit GOA1, the first test unit CT1 and the first multi-path selection circuit MUX1 may be arranged alternately in an extension direction of the first peripheral area BB1, that is, the first gate driver circuit GOA1, the first test unit CT1 and the first multi-path selection circuit MUX1 are arranged side by side in the extension direction of the first peripheral area BB1. This is beneficial to reducing a width of the first peripheral area BB1 occupied by the first circuit structure 11, and reducing a width of a non-display edge of the display panel 100, thereby achieving a narrow frame of the display device 1000.

In the embodiments of the present disclosure, an arrangement order of the first gate driver circuit GOA1, the first test unit CT1 and the first multi-path selection circuit MUX1 is not limited. The arrangement order shown in FIG. 5 is only an example but should not be construed as a limitation on the present application.

The first gate driver circuit GOA1 may be electrically connected to gates of part of TFTs included in the pixel circuit 12 by a first gate line GL1, thereby providing a gate signal to the TFTs connected to the first gate line GL1.

The first test unit CT1 may be electrically connected to at least some of the first gate lines GL1 and is configured to detect whether the first display portion 10 of the display panel 100 can emit light normally through the first test unit CT1 after the display panel 100 is manufactured and before the first driver chip 200 is bonded to the first bonding portion 30.

The first multi-path selection circuit MUX1 may be, for example, connected to a first data fan-out line Data1 and at least two first data lines DL1, and is used to, for example, transmit a data signal to each first data line DL1 in a time-sharing manner through the first data fan-out line Data1. For example, the control mode of the first multi-path selection circuit MUX1 may be 1:2, 1:3, 1:4, 1:6 or 1:8, that is, a first multi-path selection circuit MUX1 may be connected to 2, 3, 4, 6 or 8 first data lines DL1, which is not limited in the embodiments of the present disclosure.

In the embodiments of the present disclosure, the specific circuit structures of the first gate driver circuit GOA1, the first test unit CT1 and the first multi-path selection circuit MUX1 are not limited.

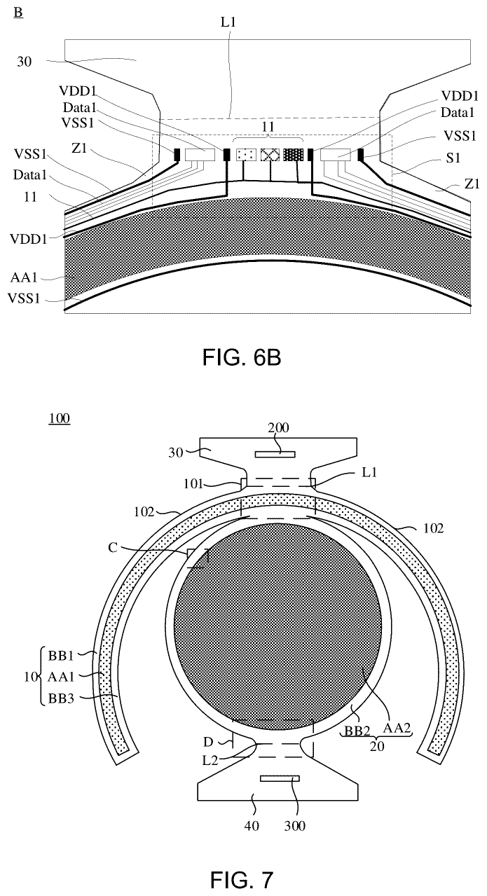

The second voltage bus VSS1 is electrically connected to cathodes of the light-emitting devices EL of the first sub-pixels P1, and is used to provide a negative power supply signal to the cathodes of the light-emitting devices EL. The cathodes of the light-emitting devices EL of the plurality of first sub-pixels P1 may be of a continuous whole-layer structure (i.e., a cathode layer). Based on this, there is no need to provide a connection line connected to the second voltage bus VSS1 in the first display area AA1. Referring to FIG. 6A, the first voltage bus VDD1, the first circuit structures 11, the first data fan-out lines Data1 and the second voltage bus VSS1 extend to the first bonding portion 30, and the first bonding portion 30 is configured to transmit corresponding signals to the first voltage bus VDD1, the first circuit structures 11, the first data fan-out lines Data1 and the second voltage bus VSS1. For example, the first bonding portion 30 is configured to transmit a positive power supply voltage signal to the first voltage bus VDD1, transmit an initial signal and a clock signal to the first circuit structure 11, transmit a data signal to the first data fan-out line Data1, and transmit a negative power supply voltage signal to the second voltage bus VSS1.

For example, as shown in FIG. 2, the first driver chip 200 is disposed on the first bonding portion 30, and the first driver chip 200 is configured to generate a signal required by at least one of the first voltage bus VDD1, the first circuit structure 11, the first data fan-out line Data1 and the second voltage bus VSS1. For example, the first driver chip 200 is a source driver chip (source driver IC), and the source driver chip is used to generate a data signal required by the first data fan-out line Data1; alternatively, the first driver chip 200 may be a display driver chip (display driver integrated circuit, DDIC), which is not specifically limited in the embodiments of the present disclosure.

It can be understood that the display device 1000 may further include, for example, a timing controller (TCON), a power management chip DC/DC, a variable resistance voltage divider circuit (for generating Vcom) and other driving circuits. The timing controller may, for example, transmit a clock control signal to the first circuit structure 11, and the power management chip DC/DC may, for example, transmit corresponding power supply signals to the first voltage bus VDD1 and the second voltage bus VSS1. The first display portion 10 achieves image display under the joint action of the first driver chip 200, the first circuit structure 11, the timing controller, the power management chip DC/DC, the variable resistance voltage divider circuit, and other electronic components and circuits.

In some embodiments, referring to FIG. 6A, FIG. 6A is a partial structural diagram of a connection area between the first display portion 10 and the first bonding portion 30. The first peripheral area BB1 includes a first fan-out area S1 and two first wiring areas Z1 located at two sides of the first fan-out area S1.

In each first wiring area Z1, in a direction perpendicular to an extension direction of the first display area AA1 and away from the first display area AA1, the first voltage bus VDD1, the first circuit structure 11, the first data fan-out line Data1 and the second voltage bus VSS1 are arranged in sequence.

In the first fan-out area S1, in an extension direction of an edge (dashed line L1) of the first fan-out area S1 proximate to the first bonding portion 30, the second voltage bus VSS1, the first data fan-out line Data1, the first voltage bus VDD1, the first circuit structure 11, the first voltage bus VDD1, the first data fan-out line Data1 and the second voltage bus VSS1 are arranged in sequence.

The above wiring method is conducive to reducing a width of the first peripheral area BB1 occupied by the first voltage bus VDD1, the first circuit structure 11, the first data fan-out line Data1 and the second voltage bus VSS1, and is conducive to reducing the width of the frame of the first display portion 10, thereby realizing a narrow frame of the display device 1000.

In some embodiments, referring to FIGS. 2 and 6B, the first display portion 10 further includes a third peripheral area BB3. The third peripheral area BB3 extends in parallel with the first display area AA1 and is located between the first display area AA1 and the second display portion 20. The third peripheral area BB3 is provided with the second voltage bus VSS1 connected to the plurality of first sub-pixels P1. Thus, the second voltage bus VSS1 may have a ring structure and surround the entire first display area AA1. The first display area AA1 is connected to the second voltage bus VSS1 on all sides, which is beneficial to reducing the resistance of the second voltage bus VSS1 and reducing the voltage drop of the second voltage bus VSS1.

For example, in the first display portion 10, cathodes of a plurality of light-emitting devices EL included in the plurality of first sub-pixels P1 are of a continuous whole-layer structure, and the second voltage bus VSS1 is connected to the cathode layer and is used to provide a negative power supply signal for the cathodes of the light-emitting devices EL.

In some embodiments, with continued reference to FIG. 6B, in the first peripheral area BB1, a distance between the second voltage bus VSS1 and an edge (hereinafter referred to as an outer edge) of the first display portion away from the second display portion may be in a range of 290 μm to 390 μm, inclusive. This is beneficial to improving the reliability of the second voltage bus VSS1. For example, in the first peripheral area BB1, a distance between the second voltage bus VSS1 and the outer edge of the first display portion is 290 μm, 340 μm, 375 μm or 390 μm, which is not listed here one by one.

A line width of a portion of the second voltage bus VSS1 located in the first peripheral area BB1 may be in a range of 400 μm to 500 μm, inclusive. This is beneficial to reducing the resistance of the second voltage bus VSS1 and reducing the voltage drop of the second voltage bus VSS1. For example, the line width of the second voltage bus VSS1 is 400 μm, 430 μm, 450 μm, 480 μm or 500 μm, which will not be described in detail here.

A maximum width of the first peripheral area BB1 occupied by the plurality of first data fan-out lines Data1 may be in a range of 130 μm to 230 μm, inclusive. This is beneficial to reducing the width of the first peripheral area BB1, thereby reducing a width of a black edge of the display device. For example, the maximum width of the first peripheral area BB1 occupied by the plurality of first data fan-out lines Data1 is 130 μm, 150 μm, 180 μm or 230 μm, which will not be described in detail here. It can be understood that in the extension direction of the first peripheral area BB1, lengths of the plurality of first data fan-out lines Data1 are different. In this way, at different positions of the first peripheral area BB1, widths of the first peripheral area BB1 occupied by the plurality of first data fan-out lines Data1 may be different. Based on this, the above maximum width may be a width of the first peripheral area BB1 occupied by part of the plurality of first data fan-out lines Data1 proximate to the first bonding portion 30.

A width of the first peripheral area BB1 occupied by the first circuit structure 11 may be in a range of 400 μm to 500 μm, inclusive. This is beneficial to reducing the width of the first peripheral area BB1, thereby reducing the width of the black edge of the display device. For example, the width of the first peripheral area BB1 occupied by the first circuit structure 11 is 400 μm, 450 μm, or 500 μm, which will not be described in detail here.

A width of a portion of the first voltage bus VDD1 located in the first peripheral area BB1 may be in a range of 30 μm to 130 μm, inclusive. In this way, the width of the portion of the first voltage bus VDD1 located in the first peripheral area BB1 may be reduced without significantly increasing the resistance of the first voltage bus VDD1, which is beneficial to reducing the width of the first peripheral area BB1. For example, the width of the first voltage bus VDD1 is 30 μm, 80 μm or 130 μm, which will not be described in detail here.

A distance between the first voltage bus VDD1 and the first display area AA1 may be in a range of 20 μm to 100 μm, inclusive. This is beneficial to reducing signal interference caused by the first voltage bus VDD1 on the pixel circuits outside the first display area AA1, thereby improving the display uniformity of the first display area AA1. For example, the distance between the first voltage bus VDD1 and the first display area AA1 is 20 μm, 60 μm, or 100 μm, which will not be described in detail here.

As shown in FIG. 6B, in a case where the third peripheral area BB3 further includes a second voltage bus VSS1, a distance between the second voltage bus VSS1 and an edge (hereinafter referred to as an inner edge) of the third peripheral area BB3 proximate to the second display portion may be in a range of 290 μm to 390 μm, inclusive. This is beneficial to improving the reliability of the second voltage bus VSS1. For example, the distance between the second voltage bus VSS1 and the inner edge of the first display portion is 290 μm, 340 μm, 375 μm or 390 μm, which will not be described in detail herein.

In some embodiments, the first display portion 10 and the second display portion 20 may be controlled separately, so that the first display portion 10 and the second display portion 20 may perform independent display, which is beneficial to enriching the application mode of the display panel 100 and enhancing the user experience.

Referring to FIG. 7, FIG. 7 is a structural diagram showing that the display panel 100 includes a second bonding portion 40 and the first display portion 10 is in a flattened state. The display panel 100 further includes the second bonding portion 40, and the second bonding portion 40 is disposed on a side of the second display portion 20 and is connected to the second display portion 20. The second bonding portion 40 may be bent to the non-display surface (not shown in the figure) of the second display portion 20.

In some embodiments, as shown in FIG. 7, the first bonding portion 30 and the second bonding portion 40 are located on two opposite sides of the second display portion 20. The first display portion 10 includes a connecting sub-portion 101 located between the first bonding portion 30 and the second display portion 20, and two extending sub-portions 102 connected to both ends of the connecting sub-portion 101. Each of ends of the two extending sub-portions 102 away from the connecting sub-portion 101 and the second bonding portion 40 have a gap therebetween. In a process that the display panel 100 is enclosed from a flattened state shown in FIG. 7 to form a three-dimensional structure, for example, the second bonding portion 40 may be bent toward a side proximate to the non-display surface of the second display portion 20, and then the two extending sub-portions 102 are bent, so that inner edges of the extending sub-portions 102 (edges proximate to the second display portion 20) surround an edge of the second display portion 20 and are connected to the edge of the second display portion 20.

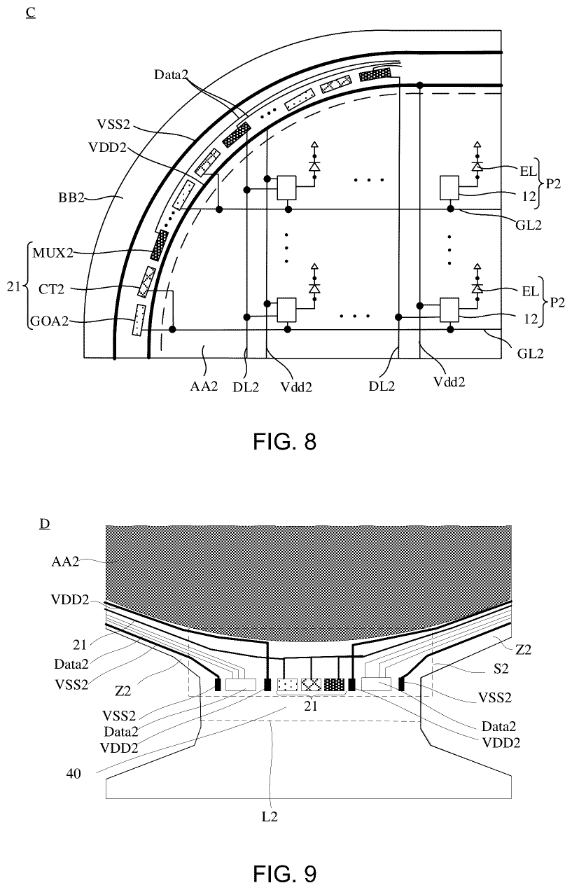

The second display portion includes 20 a second display area AA2 and a second peripheral area BB2. Referring to FIG. 8, the second display area AA2 is provided with a plurality of second sub-pixels P2. The structure of the second sub-pixel P2 may be the same as that of the first sub-pixel P1, and details are not described in detail here. For example, effective light-emitting areas of a first sub-pixel P1 and a second sub-pixel P2 for emitting light of the same color are the same in shape and equal in size, and pixel densities of the first sub-pixel P1 and the second sub-pixel P2 are substantially the same.

As shown in FIGS. 7 and 8, the second peripheral area BB2 surrounds the second display area AA2. The second peripheral area BB2 is at least provided with second circuit structures 21 and second data fan-out lines Data2 that are connected to the plurality of second sub-pixels P2. Referring to FIG. 9, the second circuit structures 21 and the second data fan-out lines Data2 extend to the second bonding portion 40, and the second bonding portion 40 is configured to transmit corresponding signals to the second circuit structures 21 and the second data fan-out lines Data2.

For example, as shown in FIG. 8, the second display area AA2 further includes a plurality of second voltage signal lines Vdd2, a plurality of second gate lines GL2 and a plurality of second data lines DL2. The second sub-pixel P2 includes a pixel circuit 12 and a light-emitting device EL. For example, the structure of the second sub-pixel P2 (including the pixel circuit 12 and the light-emitting device EL) is the same as that of the first sub-pixel P1, and details are not described in detail here.

Similar to the first circuit structure 11, the second circuit structure 21 may include a second gate driver circuit GOA2, a second test unit CT2 and a second multi-path selection circuit MUX2. The second gate driver circuit GOA2, the second test unit CT2 and the second multi-path selection circuit MUX2 may be arranged alternately in an extension direction of the second peripheral area BB2, that is, the second gate driver circuit GOA2, the second test unit CT2 and the second multi-path selection circuit MUX2 are arranged side by side in the extension direction of the second peripheral area BB2. This is beneficial to reducing a width of the second peripheral area BB2 occupied by the second circuit structure 21, and reducing a width of a non-display area (a width of a black edge) between the first display portion 10 and the second display portion 20, thereby improving the display effect of the display panel 100 and improving the effect of the display panel 100 when realizing naked-eye 3D display.

The second gate driver circuit GOA2 may be electrically connected to gates of part of TFTs included in the pixel circuit 12 by a second gate line GL2, thereby providing a gate signal to the TFTs connected to the second gate line GL2.

The second test unit CT2 may be electrically connected to at least some of the second gate line GL2 and is configured to detect whether the second display portion 20 of the display panel 100 can emit light normally through the second test unit CT2 after the display panel 100 is manufactured and before the second driver chip 300 is bonded to the second bonding portion 40.

The second multi-path selection circuit MUX2 may be, for example, connected to a second data fan-out line Data2 and at least two second data lines DL2, and is used to, for example, transmit a data signal to each second data line DL2 in a time-sharing manner through the second data fan-out line Data2. For example, the control mode of the second multi-path selection circuit MUX2 may be 1:2, 1:3, 1:4, 1:6 or 1:8, that is, a second multi-path selection circuit MUX2 may be connected to 2, 3, 4, 6 or 8 second data lines DL2, which is not limited in the embodiments of the present disclosure.

The second circuit structures 21 and the second data fan-out lines Data2 extend to the second bonding portion 40, and the second bonding portion 40 is configured to transmit corresponding signals to the second circuit structures 21 and the second data fan-out lines Data2.

In some embodiments, a line width of the first voltage bus VDD1 is substantially equal to a line width of a third voltage bus VDD2. And/or, a line width of the second voltage bus VSS1 is greater than a line width of a fourth voltage bus VSS2.

For example, a width of a portion of the third voltage bus VDD2 located in the second peripheral area BB2 may also be in a range of 30 μm to 130 μm, inclusive. In this way, the width of the third voltage bus VDD2 may be reduced while the resistance of the third voltage bus VDD2 is ensured to be relatively small, which is beneficial to reducing the width of the second peripheral area BB2. For example, the width of the third voltage bus VDD2 is 30 μm, 80 μm or 130 μm, which is not listed here one by one.

A line width of a portion of the fourth voltage bus VSS2 located in the second peripheral area BB2 may be in a range of 130 μm to 230 μm, inclusive. This is beneficial to reducing the resistance of the fourth voltage bus VSS2 and reducing the voltage drop of the fourth voltage bus VSS2. For example, the line width of the fourth voltage bus VSS2 is 130 μm, 180 μm or 230 μm, which is not listed here one by one.

In some embodiments, a distance between a portion of the fourth voltage bus VSS2 located in the second peripheral area BB2 and an edge of the second display portion may be in a range of 290 μm to 390 μm, inclusive. This is beneficial to improving the reliability of the fourth voltage bus VSS2. For example, a distance between the fourth voltage bus VSS2 and an edge of the second display portion is 290 μm, 340 μm, 375 μm or 390 μm, which is not listed here one by one.

A maximum width of the second peripheral area BB2 occupied by the plurality of second data fan-out lines Data2 may be in a range of 130 μm to 230 μm, inclusive. This is beneficial to reducing the width of the second peripheral area BB2, thereby reducing a width of a black edge of the display device. For example, the maximum width of the second peripheral area BB2 occupied by the plurality of second data fan-out lines Data2 is 130 μm, 150 μm, 180 μm or 230 μm, which will not be described in detail here.

A width of the second peripheral area BB2 occupied by the second circuit structure 21 may be in a range of 400 μm to 500 μm, inclusive. This is beneficial to reducing the width of the second peripheral area BB2, thereby reducing the width of the black edge of the second peripheral area BB2. For example, the width of the second peripheral area BB2 occupied by the second circuit structure 21 is 400 μm, 450 μm, or 500 μm, which will not be described in detail here.

A width of a portion of the third voltage bus VDD2 located in the second peripheral area BB2 may be in a range of 30 μm to 130 μm, inclusive. In this way, the width of the third voltage bus VDD2 may be reduced while the resistance of the third voltage bus VDD2 is ensured to be relatively small, which is beneficial to reducing the width of the second peripheral area BB2. For example, the width of the third voltage bus VDD2 is 30 μm, 80 μm or 130 μm, which is not listed here one by one.

A distance between a portion of the third voltage bus VDD2 located in the second peripheral area BB2 and the second display area AA2 may be in a range of 20 μm to 100 μm, inclusive. This is beneficial to reducing signal interference caused by the third voltage bus VDD2 on the pixel circuits outside the second display area AA2. For example, the distance between the third voltage bus VDD2 and the second display area AA2 is 20 μm, 60 μm or 100 μm, which is not listed here one by one.

In some embodiments, as shown in FIG. 9, a distance between a portion of the fourth voltage bus VSS2 located in the second bonding portion 40 and the second bonding portion 40 may be in a range of 250 μm to 350 μm, inclusive. For example, in the second bonding portion 40, the distance between the fourth voltage bus VSS2 and an edge of the second bonding portion 40 is 250 μm, 300 μm or 350 μm, which is not listed here one by one.

A line width of a portion of the fourth voltage bus VSS2 located in the second bonding portion 40 is smaller than a line width of a portion of the fourth voltage bus VSS2 located in the second peripheral area BB2. For example, the line width of the portion of the fourth voltage bus VSS2 located in the second bonding portion 40 may be in a range of 70 μm to 170 μm, inclusive. For example, the line width of the portion of the fourth voltage bus VSS2 located in the second bonding portion 40 is 70 μm, 120 μm or 170 μm, which are not listed here one by one.

In the second bonding portion 40, second data fan-out lines Data2 on both sides may each occupy a width of 1600 μm to 2000 μm. For example, the second data fan-out line Data2 may occupy 1600 μm, 1800 μm or 2000 μm, which is not listed here one by one.

A line width of a portion of the third voltage bus VDD2 located in the second bonding portion 40 is greater than a line width of a portion of the third voltage bus VDD2 located in the second peripheral area BB2. For example, the line width of the portion of the third voltage bus VDD2 located in the second bonding portion 40 may be in a range of 700 μm to 900 μm, inclusive. For example, the line width of the portion of the third voltage bus VDD2 located in the second bonding portion 40 is 700 μm, 800 μm or 900 μm, which is not listed here one by one.

In the second bonding portion 40, a width of the second circuit structure 21 may be in a range of 1100 μm to 1300 μm, inclusive. For example, the width of the second circuit structure 21 is 1100 μm, 1200 μm or 1300 μm, which is not listed here one by one.

In some embodiments, as shown in FIG. 9, in the second bonding portion 40, the third voltage bus VDD2, the plurality of second data fan-out lines Data2 and the fourth voltage bus VSS2 may be provided symmetrically, which is beneficial to optimizing the wiring layout on the second bonding portion 40.

For the display panel 100 provided by the embodiments of the present disclosure, as shown in FIG. 7, the first display portion 10 may display images due to the action of the first bonding portion 30 (including other electronic components electrically connected to the first bonding portion 30, such as the first driver chip 200) and the first circuit structures 11, and the second display portion 20 may display images due to the action of the second bonding portion 40 (including other electronic components electrically connected to the second bonding portion 40, such as the second driver chip 300) and the second circuit structures 21. That is, the first display portion 10 and the second display portion 20 may realize independent display.

For example, the first display portion 10 and the second display portion 20 perform independent display, or the first display portion 10 and the second display portion 20 perform synchronous display, so as to achieve the naked-eye 3D display effect; alternatively, the first display portion 10 and the second display portion 20 display at different refresh rates, or the first display portion 10 and the second display portion 20 display different image information at the same refresh rate. The display panel 100 may be configured with a variety of application scenarios, which is beneficial to improving the usage scenarios of the users.

For example, as shown in FIG. 8, the second display area AA2 may have a similar structure to the first display area AA1. For example, the second display area AA2 may include a plurality of second voltage signal lines Vdd2, a plurality of second gate lines GL2 and a plurality of second data lines DL2. The second sub-pixel P2 includes a pixel circuit 12 and a light-emitting device EL.

In some embodiments, as shown in FIG. 8, FIG. 8 is a partial enlarged view of the second display portion 20 and the second bonding portion 40. The second peripheral area BB2 is further provided with a third voltage bus VDD2 and a fourth voltage bus VSS2 that are connected to the plurality of second sub-pixels P2. The third voltage bus VDD2 may be electrically connected to pixel circuits 12 of the second sub-pixels P2 and is used to provide a positive power supply voltage signal (high voltage signal) for the second sub-pixels P2. The fourth voltage bus VSS2 may be electrically connected to cathodes of the light-emitting devices EL, and is used to provide a negative power supply signal to the cathodes of the light-emitting devices EL. In this way, the first display portion 10 and the second display portion 20 use two sets of completely independent signal control circuits and signal transmission lines, which is beneficial for the first display portion 10 and the second display portion 20 to achieving the functions of independent control and independent display.

For example, the third voltage bus VDD2 and the first voltage bus VDD1 may transmit voltage signals having the same voltage value, or transmit voltage signals having different voltage values, which is not specifically limited in the embodiments of the present disclosure. For example, the third voltage bus VDD2 and the first voltage bus VDD1 transmit the voltage signals with the same voltage value. The fourth voltage bus VSS2 and the second voltage bus VSS1 may transmit voltage signals having the same voltage value, or transmit voltage signals having different voltage values, which is not specifically limited in the embodiments of the present disclosure. For example, the fourth voltage bus VSS2 and the second voltage bus VSS1 transmit the voltage signals with the same voltage value.

Similar to the second circuit structure 21 and the second data fan-out line Data2, the third voltage bus VDD2 and the fourth voltage bus VSS2 also extend to the second bonding portion 40, and the second bonding portion 40 is further configured to transmit corresponding signals to the third voltage bus VDD2 and the fourth voltage bus VSS2.

In some embodiments, as shown in FIG. 7, the first display portion 10 includes a connecting sub-portion 101 and two extending sub-portions 102. The connecting sub-portion 101 is located between the first bonding portion 30 and the second display portion 20, and is connected to the second display portion 20. The two extending sub-portions 102 are respectively connected to two ends of the connecting sub-portion 101. There is a gap between each of the two extending sub-portions 102 and the second display portion 20 when the first display portion 10 is in a flattened state. That is, the two extending sub-portions 102 are not connected to the second display portion 20 when the first display portion 10 is in a flattened state. For example, there is no structure between each of the extending sub-portions 102 and the second display portion 20. In this way, the first display portion 10 can be fitted with the second display portion 20 well in an enclosed state, and thus a width of a non-display area between each of the extending sub-portions 102 and the second display portion 20 may be reduced, which is beneficial to improving the display effect of the display panel 100.

For example, during manufacturing the display panel 100, a continuous initial panel may be formed, and then a portion of the initial panel located between each of the extending sub-portions 102 and the second display portion 20 is removed through a cutting process to form the display panel 100 shown in FIG. 7.

In some embodiments, referring to FIG. 9, the second peripheral area BB2 includes a second fan-out area S2 and second wiring areas Z2 located at two sides of the second fan-out area S2. Since the second peripheral area BB2 is a ring-shaped area, two ends of the second wiring areas Z2 are respectively connected to two ends of the second fan-out area S2.

In the second wiring area Z2, in a direction away from the second display area AA2, the third voltage bus VDD2, the second circuit structures 21, the second data fan-out lines Data2 and the fourth voltage bus VSS2 are arranged in sequence. This is beneficial to reducing a width of the second peripheral area BB2 occupied by the third voltage bus VDD2, the second circuit structures 21, the second data fan-out lines Data2 and the fourth voltage bus VSS2, reducing a width of the non-display area of the second display portion 20, and improving a screen-to-body ratio of the second display portion 20. In order to simplify the drawing in FIG. 9, the position of the second circuit structures 21 in the second peripheral area BB2 is indicated by a line.

In the second fan-out area S2, in an extension direction of an edge (dashed line L2) of the second fan-out area S2 proximate to the second bonding portion 40, the fourth voltage bus VSS2, the second data fan-out line Data2, the third voltage bus VDD2, the second circuit structure 21, the third voltage bus VDD2, the second data fan-out line Data2 and the fourth voltage bus VSS2 are arranged in sequence. This is beneficial to optimizing the wiring layout in the second fan-out area S2 and improving the space utilization of the second fan-out area S2.

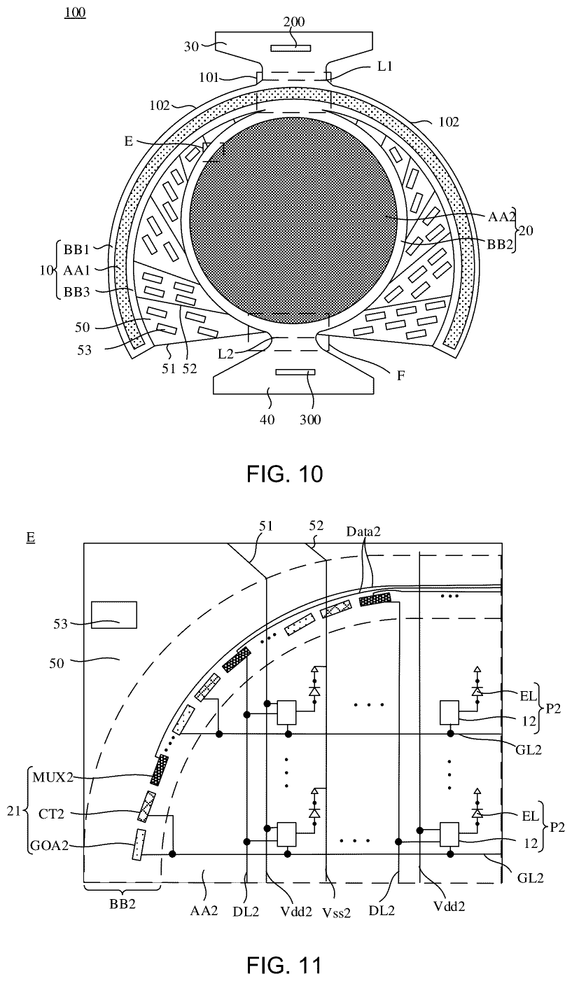

In some embodiments, as shown in FIGS. 10 and 11, FIG. 11 is a partial enlarged view of the second peripheral area BB2 and part of a connecting portion 50 when the second sub-pixels P2 are connected to the first voltage bus VDD1 and the second voltage bus VSS1. The first voltage bus VDD1 and the second voltage bus VSS1 are connected to the plurality of second sub-pixels P2. That is, the second sub-pixels P2 in the second display portion 20 and the first sub-pixels P1 in the first display portion 10 share the first voltage bus VDD1 and the second voltage bus VSS1. In this way, it is unnecessary to provide the third voltage bus VDD2 and the fourth voltage bus VSS2 in the second peripheral area BB2, and thus the width of the second peripheral area BB2 may be reduced.

Referring to FIG. 10, the first display portion 10 includes a connecting sub-portion 101 and two extending sub-portions 102. The connecting sub-portion 101 is located between the first bonding portion 30 and the second display portion 20, and is connected to the second display portion 20. The two extending sub-portions 102 are respectively connected to two ends of the connecting sub-portion 101. There is a gap between each of the two extending sub-portions 102 and the second display portion 20 when the first display portion 10 is in a flattened state.

The display panel 100 further includes two connecting portions 50. Each connecting portion 50 is located between an extending sub-portion 102 and the second display portion 20, and is connected to the extending sub-portion 102 and the second display portion 20. The connecting portion 50 may be stretched to be deformed. The connecting portion 50 includes a first voltage transfer line 51 and a second voltage transfer line 52. The first voltage transfer line 51 is connected to the first voltage bus VDD1 and the plurality of second sub-pixels P2, and the second voltage transfer line 52 is connected to the second voltage bus VSS1 and the plurality of second sub-pixels P2. The connecting portion 50 is provided to connect the first voltage bus VDD1 and the second voltage bus VSS1 to the plurality of second sub-pixels P2, which is beneficial to shortening lengths of the first voltage transfer line 51 and the second voltage transfer line 52 and reducing resistances of the first voltage transfer line 51 and the second voltage transfer line 52.

That is, an area between the extending sub-portion 102 and the second display portion 20 is not cut or removed as a whole (at least part of the area is retained), and the connecting portion 50 between the extending sub-portion 102 and the second display portion 20 may be bent or folded and bent to a backlight side of the extending sub-portion 102 and/or a backlight side of the second display portion 20. The backlight side of the extending sub-portion 102 refers to a side proximate to a non-light-exit surface of the extending sub-portion 102; and the backlight side of the second display portion 20 refers to a side proximate to a non-light-exit surface of the second display portion 20.

In some embodiments, as shown in FIG. 10, the connecting portion 50 is provided with a plurality of openings 53 therein, and the first voltage transfer line 51 and the second voltage transfer line 52 are provided bypassing the plurality of openings 53. This is beneficial to reducing the stress subjected to the connecting portion 50 during tensile deformation, reducing the risk of bending and damage of the connecting portion 50, and reducing the risk of the first voltage transfer line 51 and the second voltage transfer line 52 being broken.

For example, the opening 53 is in a shape of a circle, an ellipse, a rectangle, a square, a parallelogram, a trapezoid, and any other shape, and is not specifically limited in the embodiments of the present disclosure. It can be understood that shapes and distribution positions of the openings shown in FIG. 10 are only exemplary, and the distribution positions of the openings 53 are not specifically limited in the present disclosure.

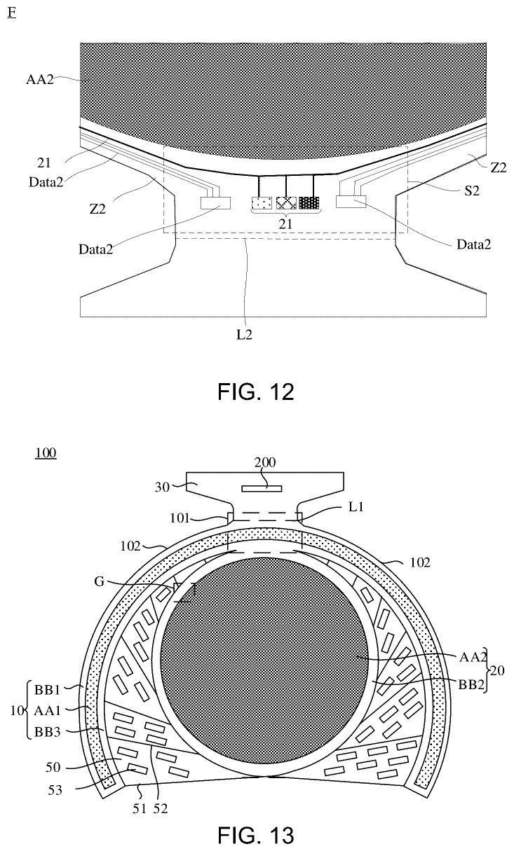

In some embodiments, referring to FIG. 12, FIG. 12 is a partial enlarged view of the second peripheral area BB2 when the second sub-pixels P2 are connected to the first voltage bus VDD1 and the second voltage bus VSS1. The second peripheral area BB2 includes a second fan-out area S2 and second wiring areas Z2 located at two sides of the second fan-out area S2.

As shown in FIG. 12, in the second wiring area Z2, the second circuit structure 21 is closer to the second display area AA2 than the second data fan-out line Data2. In the second fan-out area S2, in an extension direction of an edge (an extension direction of the dashed line L2) of the second fan-out area S2 proximate to the second bonding portion 40, the second data fan-out line Data2, the second circuit structure 21 and the second data fan-out line Data2 are sequentially arranged. This is beneficial to optimizing the wiring layout of the second peripheral area BB2 and reducing the width of the second peripheral area BB2 occupied by the second data fan-out lines Data2 and the second circuit structure 21.

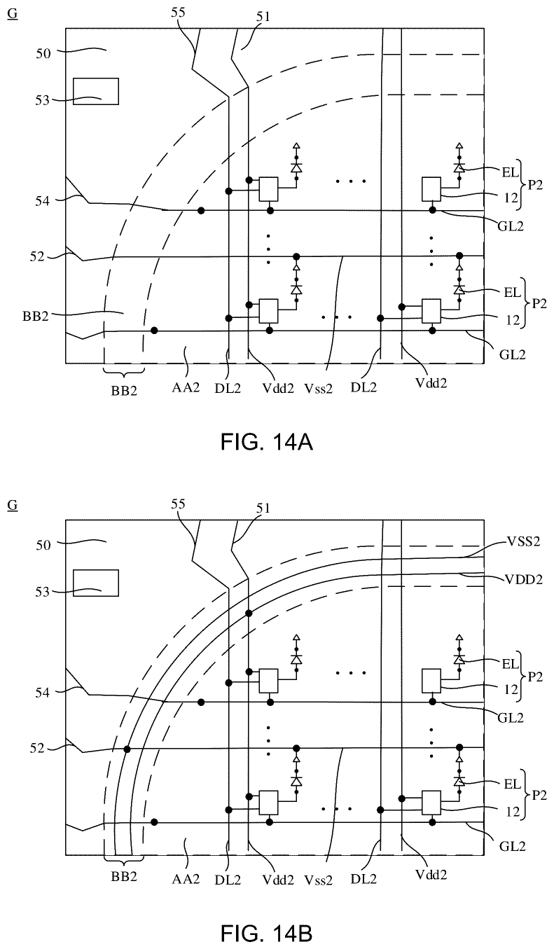

In some embodiments, in order to further reduce a width of a non-display area between the first display portion 10 and the second display portion 20, the plurality of second sub-pixels P2 included in the second display portion 20 are connected to the first voltage bus VDD1, the first circuit structures 11 and the second voltage bus VSS1 that are disposed in the first display portion 10. In this way, as shown in FIGS. 13 and 14A, the second peripheral area BB2 may not be provided with the third voltage bus VDD2, the fourth voltage bus VSS2, the second circuit structures 21, the second data fan-out lines Data2, and other structures, thereby reducing a width of the second peripheral area BB2 and reducing a width of a non-display area between the first display portion 10 and the second display portion 20.

In some embodiments, as shown in FIG. 13, the first display portion 10 includes a connecting sub-portion 101 and two extending sub-portions 102. The connecting sub-portion 101 is located between the first bonding portion 30 and the second display portion 20, and is connected to the second display portion 20. The display panel further includes two connecting portions 50. Each connecting portion 50 is located between an extending sub-portion 102 and the second display portion 20, and is connected to the extending sub-portion 102 and the second display portion 20. The connecting portion 50 may be stretched to be deformed.

As shown in FIG. 14A, the connecting portion 50 includes a first voltage transfer line 51, a second voltage transfer line (not shown in the figure), a gate signal transfer line 54 and a data signal transfer line 55. The first voltage transfer line 51 is connected to the first voltage bus VDD1 and the plurality of second sub-pixels P2, the second voltage transfer line is connected to the second voltage bus VSS1 and the plurality of second sub-pixels P2, the gate signal transfer line 54 and the data signal transfer line 55 are connected to the first circuit structure 11 and the plurality of second sub-pixels P2. For example, the gate signal transfer line 54 is connected to a first gate driver circuit GOA1 in the first circuit structure 11, and the data signal transfer line 55 is connected to the first multi-path selection circuit MUX1 in the first circuit structure 11.

In some embodiments, in a process of the connecting portion 50 being bent to a backlight side of the first display portion and/or a backlight side of the second display portion, the connecting portion 50 may be bent. In order to reduce the bending stress subjected to the transfer lines (at least including the first voltage transfer line 51, the second voltage transfer line 52, the gate signal transfer line 54 and the data signal transfer line 55) in the connecting portion 50 and reduce the risk of the transfer lines being broken, as shown in FIG. 14A, at least one of the first voltage transfer line 51, the second voltage transfer line 52, the gate signal transfer line 54 and the data signal transfer line 55 has a fold line structure (may also be set to have an arc structure), and bending portions of the first voltage transfer line 51, the second voltage transfer line 52, the gate signal transfer line 54 and the data signal transfer line 55 may be located in an area where the connecting portion 50 is bent. For example, the first voltage transfer line 51, the second voltage transfer line 52, the gate signal transfer line 54 and the data signal transfer line 55 are all configured as a fold line structure.

In some embodiments, as shown in FIG. 14B, in a case where the display panel 100 includes the connection portion 50, the second display portion 20 (the second peripheral area BB2) may include a third voltage bus VDD2 and/or a fourth voltage bus VSS2. For example, the second peripheral area BB2 may be provided with only the third voltage bus VDD2; alternatively, the second peripheral area BB2 may be provided with only the fourth voltage bus VSS2; alternatively, the second peripheral area BB2 may be provided with both the third voltage bus VDD2 and the fourth voltage bus VSS2.

For example, as shown in FIG. 14B, in a case where the second peripheral area BB2 is provided with both the third voltage bus VDD2 and the fourth voltage bus VSS2, the third voltage bus VDD2 is electrically connected to the first voltage bus VDD1 by the first voltage transfer line 51, and the fourth voltage bus VSS2 is electrically connected to the second voltage bus VSS1 by the second voltage transfer line 52. Since the third voltage bus VDD2 is electrically connected to the first voltage bus VDD1, and the fourth voltage bus VSS2 is electrically connected to the second voltage bus VSS1, impedance of the third voltage bus VDD2 and impedance of the fourth voltage bus VSS2 may be reduced, which is beneficial to reducing the line widths of the third voltage bus VDD2 and the fourth voltage bus VSS2, thereby reducing a width of the second peripheral area BB2 and reducing a width of a non-display area between the first display portion and the second display portion.

For example, a width of the third voltage bus VDD2 is less than or equal to ½ of a width of a third voltage bus VDD2 in a case where no connecting portion 50 is provided (the third voltage bus VDD2 in a case of the embodiments shown in FIG. 5). Alternatively, the width of the third voltage bus VDD2 may be substantially equal to that of the second voltage signal line Vdd2. Alternatively, the width of the third voltage bus VDD2 is less than 10 times the width of the second voltage signal line Vdd2. For example, the width of the third voltage bus VDD2 may be less than 30 μm, which is not listed one by one in the embodiments of the present disclosure.

For example, a width of the fourth voltage bus VSS2 is less than or equal to ½ of a width of a fourth voltage bus VSS2 in a case where no connecting portion 50 is provided (the fourth voltage bus VSS2 in a case of the embodiments shown in FIG. 5). Alternatively, the width of the fourth voltage bus VSS2 is less than or equal to ½ of the width of the second voltage bus VSS1. For example, the width of the fourth voltage bus VSS2 is less than 30 μm. The width of the fourth voltage bus VSS2 is not listed one by one in the embodiments of the present disclosure.

In some embodiments, as shown in FIG. 13, the connecting portion 50 is provided with a plurality of openings 53 therein, and the first voltage transfer line 51, the second voltage transfer line 52, the gate signal transfer line 54 and the data signal transfer line 55 are provided bypassing the plurality of openings 53. This is beneficial to reducing the stress subjected to the connecting portion 50 during tensile deformation, reducing the risk of bending and damage of the connecting portion 50, and reducing the risk of the first voltage transfer line 51 and the second voltage transfer line 52 being broken.

In some embodiments, the first display portion 10 includes a plurality of first sub-pixels P1, and the plurality of first sub-pixels P1 are arranged in a plurality of rows and a plurality of columns. The second display portion 20 includes a plurality of second sub-pixels P2, and the plurality of second sub-pixels P2 are arranged in a plurality of rows and a plurality of columns.

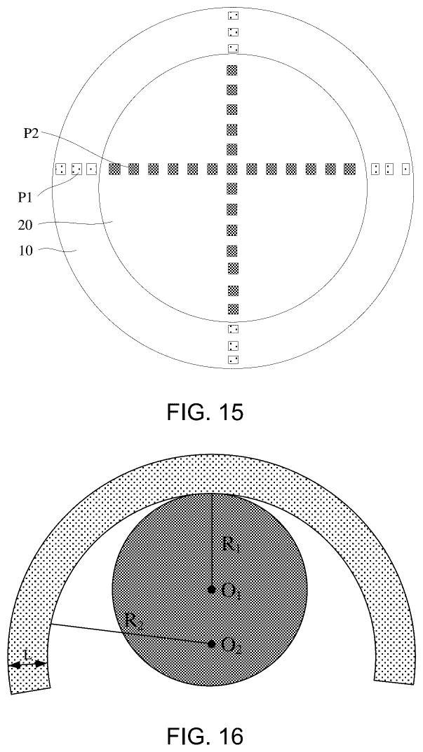

As shown in FIG. 15, FIG. 15 is a top view of the display panel 100 in a case where the first display portion 10 is in an enclosed state. A projection of a row direction (horizontal direction in FIG. 13) in which the plurality of first sub-pixels P1 are arranged on the reference plane is parallel to a projection of a row direction (horizontal direction in FIG. 13) in which the plurality of second sub-pixels P2 are arranged on the reference plane, and a projection of a column direction (vertical direction in FIG. 13) in which the plurality of first sub-pixels P1 are arranged on the reference plane is parallel to a projection of a column direction (vertical direction in FIG. 13) in which the plurality of second sub-pixels are arranged on the reference plane. The reference plane is a plane where a display surface of the second display portion 20 is located. In this way, when the first display portion 10 and the second display portion 20 synchronously display images, distortion between images displayed by the first display portion 10 and images displayed by the second display portion 20 may be avoided, thereby improving the 3D display effect of the display panel 100.

In some embodiments, as shown in FIGS. 4 and 16, FIG. 16 is a schematic structural diagram of the first display portion 10 and the second display portion 20.

In a case where the second display portion 20 is circular, and the first display portion 10 is annular in an enclosed state, a radius of the second display portion 20 is R₁, and a width of the first display portion 10 is L; when the first display portion 10 is in a flattened state, a radius of a circle where an inner border of the first display portion 10 is located is R₂; an included angle between the second display portion in the enclosed state and the first display portion 10 is α; and a thickness of the display panel is H. The following formulas (1) and (2) are satisfied.

$$H = L Sin ( π - α ) and \\ {R}_{2} = \frac{{R}_{1} L}{\sqrt{{L}^{2} - {H}^{2}}} . \qquad ( 2 )$$

According to the above formula (1) and (2), a specific size of the display panel 100 may be designed as required, and details are not described in the embodiments of the present disclosure.

It can be understood that the shape of the second display portion 20 may be, for example, an ellipse, a square, a rectangle, or a quadrilateral with four arc-shaped corners, which is not specifically limited in the embodiments of the present disclosure.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a first display portion and a second display portion, wherein the first display portion surrounds the second display portion in an enclosed state and has an included angle with the second display portion; the second display portion; the second display portion includes a display surface and a non-display surface that are opposite to each other; and
a first bonding portion disposed on a side of the first display portion and connected to the first display portion; the first bonding portion being capable of being bent to the non-display surface of the second display portion; wherein
the first display portion includes a first display area and a first peripheral area; the first display area is provided with a plurality of first sub-pixels therein; the first peripheral area extends in parallel with the first display area and is located on a side of the first display area away from the second display portion; the first peripheral area is provided therein with a first voltage bus, first circuit structures, first data fan-out lines and a second voltage bus that are connected to the plurality of first sub-pixels; and
the first voltage bus, the first circuit structures, the first data fan-out lines and the second voltage bus extend to the first bonding portion, and the first bonding portion is configured to transmit corresponding signals to the first voltage bus, the first circuit structures, the first data fan-out lines and the second voltage bus.

2. The display panel according to claim 1, wherein the second display portion includes:
a second display area provided with a plurality of second sub-pixels therein; and
a second peripheral area surrounding the second display area; the second peripheral area being at least provided therein with second circuit structures and second data fan-out lines that are connected to the plurality of second sub-pixels; and
the display panel further comprises:
a second bonding portion disposed on a side of the second display portion and connected to the second display portion; the second bonding portion being capable of being bent to the non-display surface of the second display portion; wherein
the second circuit structures and the second data fan-out lines extend to the second bonding portion, and the second bonding portion is configured to transmit corresponding signals to the second circuit structures and the second data fan-out lines.

3. The display panel according to claim 2, wherein the second peripheral area is further provided therein with a third voltage bus and a fourth voltage bus that are connected to the plurality of second sub-pixels; and
the third voltage bus and the fourth voltage bus extend to the second bonding portion, and the second bonding portion is further configured to transmit corresponding signals to the third voltage bus and the fourth voltage bus.

4. The display panel according to claim 3, wherein the first display portion includes:
a connecting sub-portion located between the first bonding portion and the second display portion and connected to the second display portion; and
two extending sub-portions respectively connected to two ends of the connecting sub-portion; each of the two extending sub-portions of the first display portion and the second display portion have a gap therebetween in a flattened state.

5. The display panel according to claim 3, wherein the second peripheral area includes a second fan-out area and second wiring areas located at two sides of the second fan-out area;
in a second wiring area, in a direction from the second display area to the second wiring area, the third voltage bus, the second circuit structures, the second data fan-out lines and the fourth voltage bus are arranged in sequence; and
in the second fan-out area, in an extension direction of an edge of the second fan-out area proximate to the second bonding portion, the fourth voltage bus, a second data fan-out line, the third voltage bus, the second circuit structures, the third voltage bus, a second data fan-out line and the fourth voltage bus are arranged in sequence.

6. The display panel according to claim 3, wherein
a line width of the first voltage bus is substantially equal to a line width of the third voltage bus; and/or
a line width of the second voltage bus is greater than a line width of the fourth voltage bus; and/or
a line width of a portion of the first voltage bus located in the second peripheral area is in a range of 30 μm to 130 μm, inclusive; a line width of a portion of the second voltage bus located in the second peripheral area is in a range of 400 μm to 500 μm, inclusive; a line width of a portion of the third voltage bus located in the second peripheral area is in a range of 30 μm to 130 μm, inclusive; and a line width of a portion of the fourth voltage bus located in the second peripheral area is in a range of 130 μm to 230 μm, inclusive.

7. (canceled)

8. The display panel according to claim 2, wherein the first voltage bus and the second voltage bus are connected to the plurality of second sub-pixels.

9. The display panel according to claim 8, wherein the first display portion includes:
a connecting sub-portion located between the first bonding portion and the second display portion and connected to the second display portion; and
two extending sub-portions respectively located at two sides of the connecting sub-portion and connected to two ends of the connecting sub-portion; and
the display panel further comprises:
two connecting portions, wherein each connecting portion is located between an extending sub-portion and the second display portion and is connected to both the extending sub-portion and the second display portion; the connecting portion is capable of being stretched to be deformed; the connecting portion includes a first voltage transfer line and a second voltage transfer line, the first voltage transfer line is connected to the first voltage bus and the plurality of second sub-pixels, and the second voltage transfer line is connected to the second voltage bus and the plurality of second sub-pixels.

10. The display panel according to claim 9, wherein the connecting portion is provided with a plurality of openings therein, and the first voltage transfer line and the second voltage transfer line are disposed bypassing the plurality of openings.

11. The display panel according to claim 8, wherein the second peripheral area includes a second fan-out area and second wiring areas located at two sides of the second fan-out area;
in a second wiring area, the second circuit structures are closer to the second display area than the second data fan-out lines; and
in the second fan-out area, in an extension direction of an edge of the second fan-out area proximate to the second bonding portion, a second data fan-out line, the second circuit structures, and a second data fan-out line are arranged in sequence.

12. The display panel according to claim 4, wherein the first bonding portion and the second bonding portion are disposed on two opposite sides of the second display portion; and
each of ends of the two extending sub-portions away from the connecting sub-portion and the second bonding portion have a gap therebetween.

13. The display panel according to claim 1, wherein the second display portion includes a plurality of second sub-pixels; and
the first voltage bus, the first circuit structures and the second voltage bus are further connected to the plurality of second sub-pixels.

14. The display panel according to claim 13, wherein the first display portion includes:
a connecting sub-portion located between the first bonding portion and the second display portion and connected to the second display portion; and
two extending sub-portions respectively located at two sides of the connecting sub-portion and connected to two ends of the connecting sub-portion; and
the display panel further comprises:
two connecting portions, wherein each connecting portion is located between an extending sub-portion and the second display portion and is connected to both the extending sub-portion and the second display portion; the connecting portion is capable of being stretched to be deformed; the connecting portion includes a first voltage transfer line, a second voltage transfer line, a gate signal transfer line and a data signal transfer line; the first voltage transfer line is connected to the first voltage bus and the plurality of second sub-pixels, the second voltage transfer line is connected to the second voltage bus and the plurality of second sub-pixels, and the gate signal transfer line and the data signal transfer line are connected to the first circuit structures and the plurality of second sub-pixels.

15. (canceled)

16. The display panel according to claim 1, wherein the first peripheral area includes a first fan-out area and two first wiring areas located at two sides of the first fan-out area;
in each first wiring area, in a direction perpendicular to an extension direction of the first display area and from the first display area to the first wiring area, the first voltage bus, the first circuit structures, the first data fan-out lines and the second voltage bus are arranged in sequence; and
in the first fan-out area, in an extension direction of an edge of the first fan-out area proximate to the first bonding portion, the second voltage bus, a first data fan-out line, the first voltage bus, the first circuit structures, the first voltage bus, a first data fan-out line and the second voltage bus are arranged in sequence.

17. The display panel according to claim 16, wherein the first display portion further includes:
a third peripheral area extending in parallel with the first display area and located between the first display area and the second display portion; the third peripheral area being provided therein with another second voltage bus connected to the plurality of first sub-pixels.

18. The display panel according to claim 1, wherein the first display portion includes a plurality of first sub-pixels, and the plurality of first sub-pixels are arranged in a plurality of rows and a plurality of columns; the second display portion includes a plurality of second sub-pixels, and the plurality of second sub-pixels are arranged in a plurality of rows and a plurality of columns; and
a projection of a row direction in which the plurality of first sub-pixels are arranged on a reference plane is parallel to a projection of a row direction in which the plurality of second sub-pixels are arranged on the reference plane, and a projection of a column direction in which the plurality of first sub-pixels are arranged on the reference plane is parallel to a projection of a column direction in which the plurality of second sub-pixels are arranged on the reference plane; the reference plane is a plane where the display surface of the second display portion is located.

19. The display panel according to claim 1, wherein the second display portion is circular, and the first display portion is annular in the enclosed state; and
a radius of the second display portion is R₁, and a width of the first display portion is L; a radius of a circle where an inner border of the first display portion in a flattened state is located is R₂; an included angle between the second display portion and the first display portion in the enclosed state is α; and a thickness of the display panel is H; wherein H=L Sin(π−α) and
$${R}_{2} = \frac{{R}_{1} L}{\sqrt{{L}^{2} - {H}^{2}}} .$$

20. The display panel according to claim 2, wherein
a first circuit structure includes a first gate driver circuit, a first test circuit and a first multi-path selection circuit; the first gate driver circuit, the first test circuit and the first multi-path selection circuit are arranged side by side in an extension direction of the first peripheral area; and/or
a second circuit structure includes a second gate driver circuit, a second test circuit and a second multi-path selection circuit; the second gate driver circuit, the second test circuit and the second multi-path selection circuit are arranged side by side in an extension direction of the second peripheral area.

21. A display device, comprising:
the display panel according to claim 1; and
a first driver chip disposed on the first bonding portion of the display panel and configured to transmit a signal to the first bonding portion.

22. The display device according to claim 21, wherein the display panel further includes a second bonding portion, and the second bonding portion is connected to the second display portion of the display panel;
the display device further comprises:
a second driver chip disposed on the second bonding portion and configured to transmit a signal to the second bonding portion.
